(19) United States
(12) Patent Application Publication
(10) Pub. No.: US 2024/0234267 A1
(43) Pub. Date: Jul. 11, 2024

(54) SEMICONDUCTOR DEVICE

(71) Applicant: ROHM CO., LTD., Kyoto (JP)

(72) Inventors: Shinya UMEKI, Kyoto (JP); Yuta KAWAMOTO, Kyoto (JP); Ryosuke FUKUDA, Kyoto (JP)

(73) Assignee: ROHM CO., LTD., Kyoto (JP)

(21) Appl. No.: 18/610,280

(22) Filed: Mar. 20, 2024

Related U.S. Application Data
(63) Continuation of application No. PCT/JP22/39667, filed on Oct. 25, 2022.

(30) Foreign Application Priority Data
Nov. 16, 2021 (JP) 2021-186162

(51) Int. Cl. H01L 23/495; H01L 23/31

(52) U.S. Cl. CPC H01L 23/49575; H01L 23/3107; H01L 23/4952; H01L 23/49562; H01L 23/49568

(57) ABSTRACT

A semiconductor device comprises: a first semiconductor chip including a first obverse surface and a first reverse surface spaced apart from each other in a thickness direction; a second semiconductor chip including a second obverse surface and a second reverse surface spaced apart from each other in the thickness direction, and electrically connected in series to the first semiconductor chip; and a conductive member including a first conductive plate electrically connected to the first semiconductor chip and the second semiconductor chip. At least one of the first semiconductor chip and the second semiconductor chip is an IGBT including a collector electrode, an emitter electrode, and a gate electrode. The first conductive plate is provided between the first semiconductor chip and the second semiconductor chip in the thickness direction.

### CROSS-REFERENCE TO RELATED APPLICATIONS

This application is a continuation of International Application No. PCT/JP2022/039667, filed Oct. 25, 2022, which claims priority to JP 2021-186162, filed Nov. 16, 2021, the entire contents of each are incorporated herein by reference.

### TECHNICAL FIELD

The present disclosure relates to a semiconductor device.

### BACKGROUND ART

Conventionally, a semiconductor device including a plurality of semiconductor chips arranged in multiple stages is known. JP-A-2007-123466 discloses a semiconductor device including a plurality of semiconductor chips arranged in multiple stages. The semiconductor device described in JP-A-2007-123466 has an advantage of having a reduced mounting area when the semiconductor device is mounted on the circuit board of an electric device or the like.

### BRIEF DESCRIPTION OF THE DRAWINGS

FIG. 1 is a plan view showing a semiconductor device according to a first embodiment.

FIG. 2 corresponds to the plan view of FIG. 1, and indicates a sealing resin with an imaginary line.

FIG. 3 corresponds to the plan view of FIG. 2, and indicates a third conductive plate with an imaginary line.

FIG. 4 corresponds to the plan view of FIG. 3 and indicates a second semiconductor chip and a first conductive plate with imaginary lines, with a second connecting member and the third conductive plate being omitted.

FIG. 5 is a cross-sectional view along line V-V in FIG. 2.

FIG. 6 is a cross-sectional view along line VI-VI in FIG. 2.

FIG. 7 is a cross-sectional view along line VII-VII in FIG. 2.

FIG. 8 is a cross-sectional view along line VIII-VIII in FIG. 2.

FIG. 9 is a cross-sectional view along line IX-IX in FIG. 2.

FIG. 10 shows an example of the circuit configuration of the semiconductor device according to the first embodiment.

FIG. 11 is a plan view showing a semiconductor device according to a second embodiment, with a sealing resin indicated with an imaginary line.

FIG. 12 corresponds to the plan view of FIG. 11, and indicates a third conductive plate with an imaginary line.

FIG. 13 corresponds to the plan view of FIG. 12 and indicates a second semiconductor chip and a first conductive plate with imaginary lines, with a second connecting member and the third conductive plate being omitted.

FIG. 14 is a cross-sectional view along line XIV-XIV in FIG. 11.

FIG. 15 shows an example of the circuit configuration of the semiconductor device according to the second embodiment.

FIG. 16 is a plan view showing a semiconductor device according to a third embodiment.

FIG. 17 corresponds to the plan view of FIG. 16, and indicates a sealing resin with an imaginary line.

FIG. 18 corresponds to the plan view of FIG. 17, and indicates a third conductive plate and a second input terminal with imaginary lines.

FIG. 19 corresponds to the plan view of FIG. 18 and indicates a second semiconductor chip, a first conductive plate, and an output terminal with imaginary lines, with a second connecting member, the third conductive plate, and the second input terminal being omitted.

FIG. 20 is a cross-sectional view along line XX-XX in FIG. 17.

FIG. 21 is a cross-sectional view along line XXI-XXI in FIG. 17.

FIG. 22 is a plan view showing a semiconductor device according to a fourth embodiment, with a sealing resin indicated with an imaginary line.

FIG. 23 corresponds to the plan view of FIG. 22, and indicates a third conductive plate and a second input terminal with imaginary lines.

FIG. 24 corresponds to the plan view of FIG. 23 and indicates a second semiconductor chip, a first conductive plate, and an output terminal with imaginary lines, with a second connecting member, the third conductive plate, and the second input terminal being omitted.

FIG. 25 is a cross-sectional view showing a semiconductor device according to a variation.

FIG. 26 is a cross-sectional view showing a semiconductor device according to a variation.

FIG. 27 is a cross-sectional view showing a semiconductor device according to a variation.

FIG. 28 is a cross-sectional view showing a semiconductor device according to a variation.

FIG. 29 shows an example of the circuit configuration of a semiconductor device according to a variation.

FIG. 30 shows an example of the circuit configuration of a semiconductor device according to a variation.

### DETAILED DESCRIPTION OF EMBODIMENTS

The following describes preferred embodiments of a semiconductor device according to the present disclosure with reference to the drawings. In the following, the same or similar constituent elements are denoted by the same reference numerals, and the descriptions thereof are omitted. The terms such as “first”, “second” and “third” in the present disclosure are used merely as labels and are not necessarily intended to impose orders on the items to which these terms refer.

In the present disclosure, the phrases “an object A is formed in an object B” and “an object A is formed on an object B” include, unless otherwise specified, “an object A is formed directly in/on an object B” and “an object A is formed in/on an object B with another object interposed between the object A and the object B”. Similarly, the phrases “an object A is disposed in an object B” and “an object A is disposed on an object B” include, unless otherwise specified, “an object A is disposed directly in/on an object B” and “an object A is disposed in/on an object B with another object interposed between the object A and the object B”. Similarly, the phrase “an object A is located on an object B” includes, unless otherwise specified, “an object A is located on an object B in contact with the object B” and “an object A is located on an object B with another object interposed between the object A and the object B”. Furthermore, the phrase “an object A overlaps with an object B as viewed in a certain direction” includes, unless otherwise specified, “an object A overlaps with the entirety of an object B” and “an object A overlaps with a portion of an object B”.

### First Embodiment

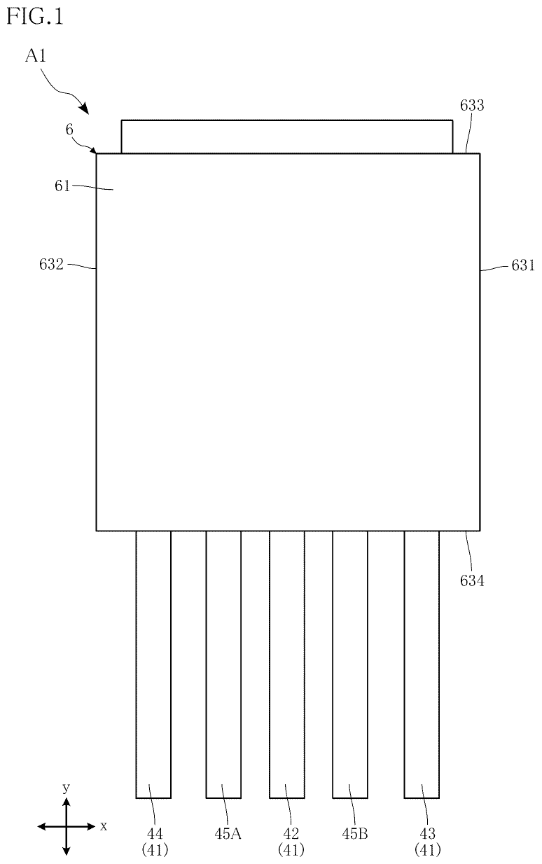

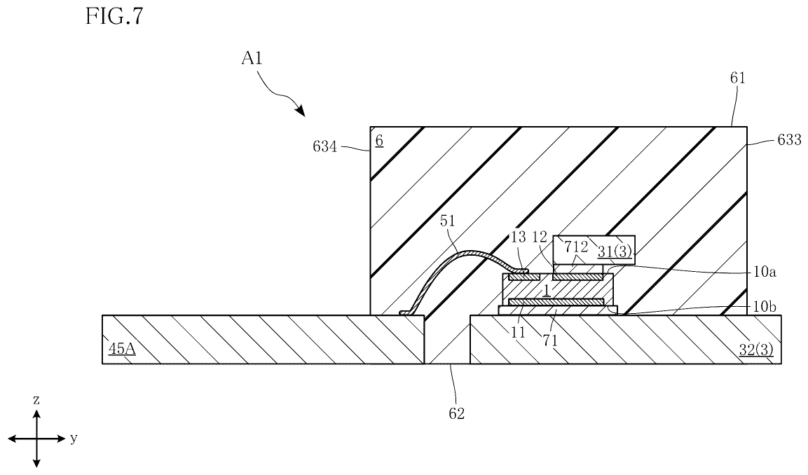

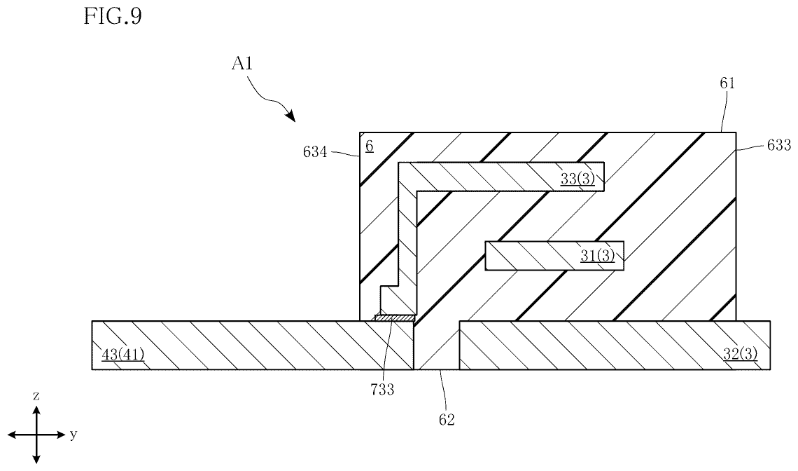

FIGS. 1 to 10 show a semiconductor device A1 according to a first embodiment. The semiconductor device A1 includes a first semiconductor chip 1, a first diode chip 19, a second semiconductor chip 2, a second diode chip 29, a conductive member 3, a plurality of power terminals 41, a first signal terminal 45A, a second signal terminal 45B, a first connecting member 51, a second connecting member 52, and a sealing resin 6.

For convenience of explanation, the thickness direction of the semiconductor device A1 is referred to as a “thickness direction z”. In the following description, one side in the thickness direction z may be referred to as “upward”, and the other side as “downward”. The terms such as “top”, “bottom”, “upward”, “downward”, “upper surface”, and “lower surface” are used to indicate the relative positions of elements and components in the thickness direction z, and do not necessarily define the relationship with respect to the direction of gravity. Also, “plan view” refers to the view seen in the thickness direction z. A direction perpendicular to the thickness direction z is referred to as a “first direction x”. The direction perpendicular to the thickness direction z and the first direction x is referred to as a “second direction y”. The first direction x is the horizontal direction in a plan view (see FIG. 1) of the semiconductor device A1. The second direction y is the vertical direction in a plan view (see FIG. 1) of the semiconductor device A1.

The semiconductor device A1 is mounted by inserting a terminal portion into a through-hole in the circuit board an electric device or the like, and has a TO (transistor outline) package structure, for example.

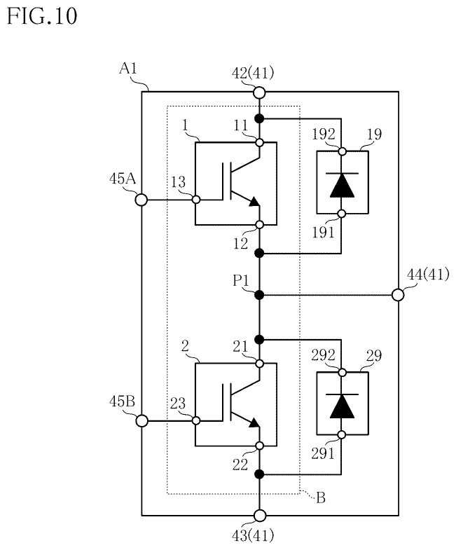

The first semiconductor chip 1 and the second semiconductor chip 2 form the functional core of the semiconductor device A1. As shown in FIG. 10, the first semiconductor chip 1 and the second semiconductor chip 2 according to the present embodiment are IGBTs, for example. Each of the first semiconductor chip 1 and the second semiconductor chip 2 is arranged such that the thickness direction thereof coincides with the thickness direction of the semiconductor device A1.

The first semiconductor chip 1 has a first obverse surface 10a and a first reverse surface 10b. The first obverse surface 10a and the first reverse surface 10b are spaced apart from each other in the thickness direction z. The first obverse surface 10a faces upward in the thickness direction z, and the first reverse surface 10b faces downward in the thickness direction z.

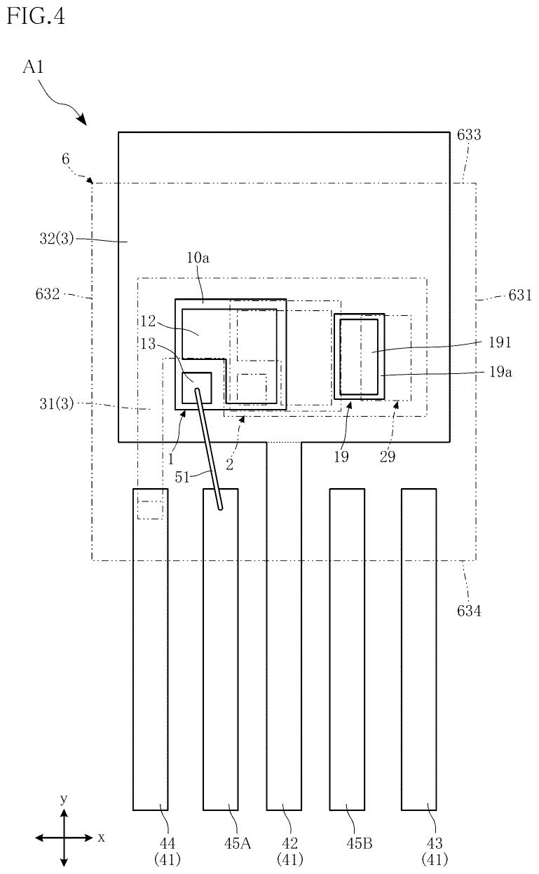

The first semiconductor chip 1 has a first collector electrode 11, a first emitter electrode 12, and a first gate electrode 13. The first collector electrode 11 is arranged on the first reverse surface 10b, and the first emitter electrode 12 and the first gate electrode 13 are arranged on the first obverse surface 10a. In the example shown in FIG. 4, the first gate electrode 13 is arranged at the corner portion (near the lower left corner in FIG. 4) of the first obverse surface 10a on a second side in the first direction x and on a second side in the second direction y.

The first gate electrode 13 of the first semiconductor chip 1 receives a gate signal (gate voltage). The gate signal inputted to the first gate electrode 13 is referred to as a “first gate signal”. The first semiconductor chip 1 switches between a conductive state and a non-conductive state according to the first gate signal. When the first semiconductor chip 1 is in a conductive state, a forward current flows from the first collector electrode 11 to the first emitter electrode 12. When the first semiconductor chip 1 is in a non-conductive state, the forward current does not flow from the first collector electrode 11 to the first emitter electrode 12. The repetitive switching of the first semiconductor chip 1 between a conductive state and a non-conductive state is referred to as a switching operation of the first semiconductor chip 1.

The first diode chip 19 is a freewheeling diode. The first diode chip 19 is provided to suppress the flow of a reverse current (a current flowing from the first emitter electrode 12 to the first collector electrode 11) through the first semiconductor chip 1. The first diode chip 19 is connected in reverse parallel to the first semiconductor chip 1. In the example shown in FIG. 4, the first semiconductor chip 1 and the first diode chip 19 are adjacent to each other in the first direction x. Specifically, the first diode chip 19 is positioned on a first side in the first direction x with respect to the first semiconductor chip 1. Unlike this configuration, the first diode chip 19 maybe arranged on the second side in the first direction x with respect to the first semiconductor chip 1, or may be adjacent to the first semiconductor chip 1 in the second direction y.

The first diode chip 19 has an obverse surface 19a and a reverse surface 19b. The obverse surface 19a and the reverse surface 19b are spaced apart from each other in the thickness direction z. The obverse surface 19a faces upward in the thickness direction z, and the reverse surface 19b faces downward in the thickness direction z. Thus, the obverse surface 19a faces in the same direction as the first obverse surface 10a, and the reverse surface 19b faces in the same direction as the first reverse surface 10b.

The first diode chip 19 has an anode electrode 191 and a cathode electrode 192. The anode electrode 191 is arranged on the obverse surface 19a, and the cathode electrode 192 is arranged on the reverse surface 19b. The anode electrode 191 is electrically connected to the first emitter electrode 12 of the first semiconductor chip 1, and the cathode electrode 192 is electrically connected to the first collector electrode 11 of the first semiconductor chip 1.

The second semiconductor chip 2 has a second obverse surface 20a and a second reverse surface 20b. The second obverse surface 20a and the second reverse surface 20b are spaced apart from each other in the thickness direction z. The second obverse surface 20a faces upward in the thickness direction z, and the second reverse surface 20b faces downward in the thickness direction z.

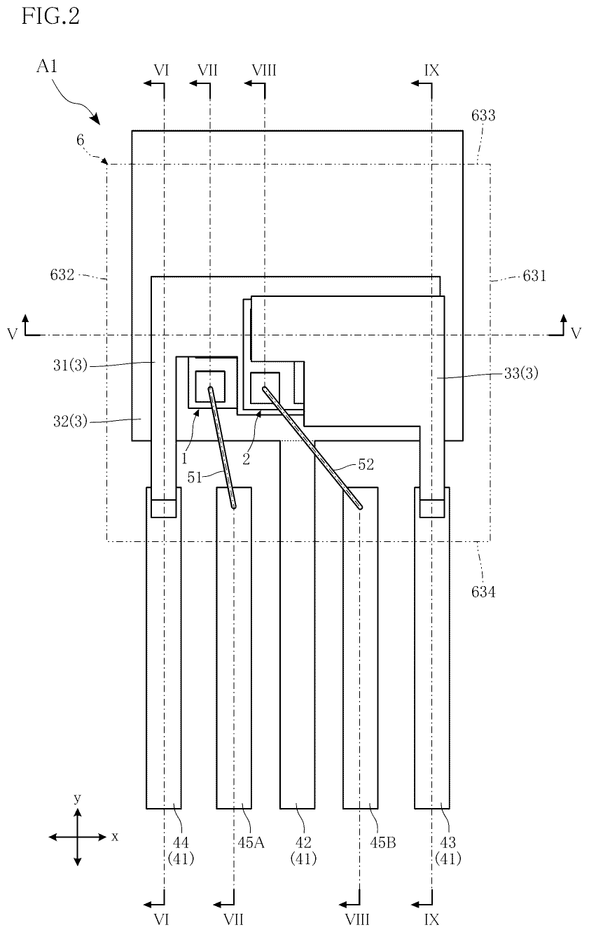

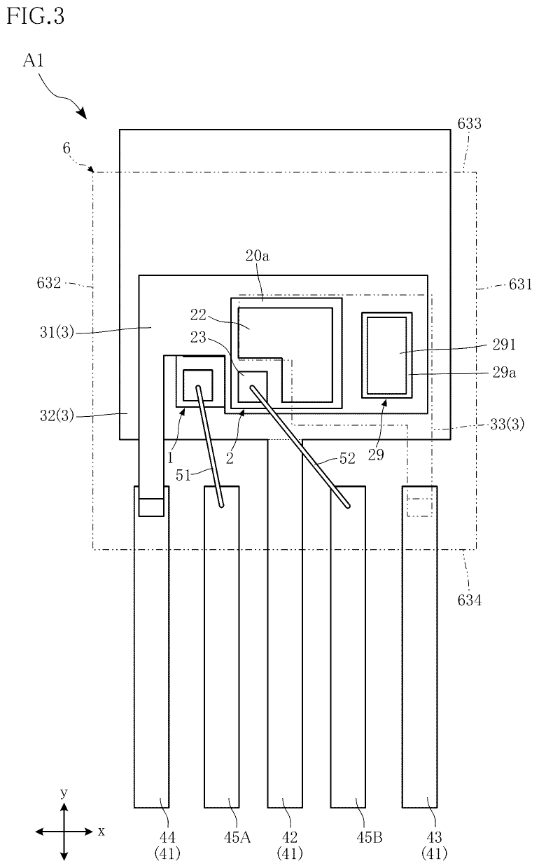

The second semiconductor chip 2 has a second collector electrode 21, a second emitter electrode 22, and a second gate electrode 23. The second collector electrode 21 is arranged on the second reverse surface 20b, and the second emitter electrode 22 and the second gate electrode 23 are arranged on the second obverse surface 20a. In the example shown in FIG. 3, the second gate electrode 23 is arranged at the corner portion (near the lower left corner in FIG. 3) of the first obverse surface 20a on the second side in the first direction x and on the second side in the second direction y. As can be understood from FIGS. 2 to 5, the second semiconductor chip 2 is arranged such that at least a portion of the second collector electrode 21 overlaps with the first emitter electrode 12 in plan view.

The second gate electrode 23 of the second semiconductor chip 2 receives a gate signal (gate voltage). The gate signal inputted to the second gate electrode 23 is referred to as a “second gate signal”. The second semiconductor chip 2 switches between a conductive state and a non-conductive state according to the second gate signal. When the second semiconductor chip 2 is in a conductive state, a forward current flows from the second collector electrode 21 to the second emitter electrode 22. When the second semiconductor chip 2 is in a non-conductive state, the forward current does not flow from the second collector electrode 21 to the second emitter electrode 22. The repetitive switching of the second semiconductor chip 2 between a conductive state and a non-conductive state is referred to as a switching operation of the second semiconductor chip 2.

The second diode chip 29 is a freewheeling diode. The second diode chip 29 is provided to suppress the flow of a reverse current (a current flowing from the second emitter electrode 22 to the second collector electrode 21) through the second semiconductor chip 2. The second diode chip 29 is connected in reverse parallel to the second semiconductor chip 2. In the example shown in FIG. 3, the second semiconductor chip 2 and the second diode chip 29 are adjacent to each other in the first direction x. Specifically, the second diode chip 29 is positioned on the first side in the first direction x with respect to the second semiconductor chip 2. Unlike this configuration, the second diode chip 29 maybe arranged on the second side in the first direction x with respect to the second semiconductor chip 2, or may be adjacent to the second semiconductor chip 2 in the second direction y.

The second diode chip 29 has an obverse surface 29a and a reverse surface 29b. The obverse surface 29a and the reverse surface 29b are spaced apart from each other in the thickness direction z. The obverse surface 29a faces upward in the thickness direction z, and the reverse surface 29b faces downward in the thickness direction z. Thus, the obverse surface 29a faces in the same direction as the second obverse surface 20a, and the reverse surface 29b faces in the same direction as the second reverse surface 20b.

The second diode chip 29 has an anode electrode 291 and a cathode electrode 292. The anode electrode 291 is arranged on the obverse surface 29a, and the cathode electrode 292 is arranged on the reverse surface 29b. The anode electrode 291 is electrically connected to the second emitter electrode 22 of the second semiconductor chip 2, and the cathode electrode 292 is electrically connected to the second collector electrode 21 of the second semiconductor chip 2.

As shown in FIG. 10, the first semiconductor chip 1 and the second semiconductor chip 2 are electrically connected to each other in series. Specifically, the first emitter electrode 12 of the first semiconductor chip 1 and the second collector electrode 21 of the second semiconductor chip 2 are electrically connected to each other. Thus, as shown in FIG. 10, the first semiconductor chip 1 and the second semiconductor chip 2 form a bridge B in which the first semiconductor chip 1 serving as an upper arm is connected to the second semiconductor chip 2 serving as a lower arm.

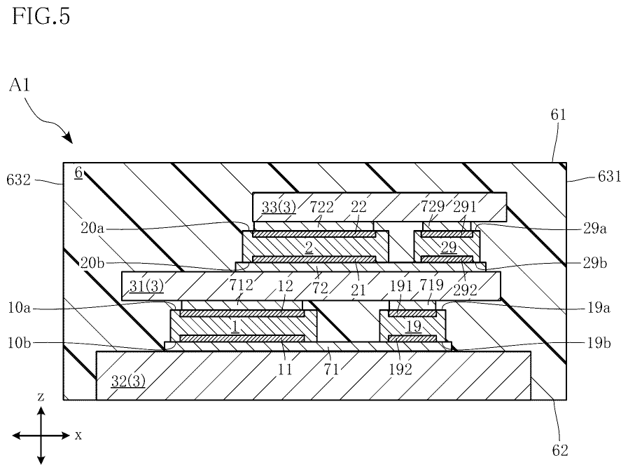

As can be understood from FIGS. 4 and 5, the first semiconductor chip 1 and the second semiconductor chip 2 overlap with each other in plan view. The second semiconductor chip 2 overlaps with the first diode chip 19 in plan view. In the illustrated example, the area in which the second semiconductor chip 2 overlaps with the first semiconductor chip 1 is larger than the area in which the second semiconductor chip 2 overlaps with the first diode chip 19 in plan view. Unlike this configuration, the area in which the second semiconductor chip 2 overlaps with the first semiconductor chip 1 maybe smaller than the area in which the second semiconductor chip 2 overlaps with the first diode chip 19 in plan view. The first diode chip 19 and the second diode chip 29 overlap with each other in plan view. Unlike this configuration, the first diode chip 19 and the second diode chip 29 may not overlap with each other in plan view.

The conductive member 3 forms a conductive path connecting the first semiconductor chip 1 and the second semiconductor chip 2 to the power terminals 41. The conductive member 3 is made of copper or a copper alloy, for example, but may be made of another metal member. The conductive member 3 includes a first conductive plate 31, a second conductive plate 32, and a third conductive plate 33. The first conductive plate 31, the second conductive plate 32, and the third conductive plate 33 are spaced apart from each other. As can be understood from FIGS. 2 to 5, the first conductive plate 31, the second conductive plate 32, and the third conductive plate 33 overlap with each other in plan view.

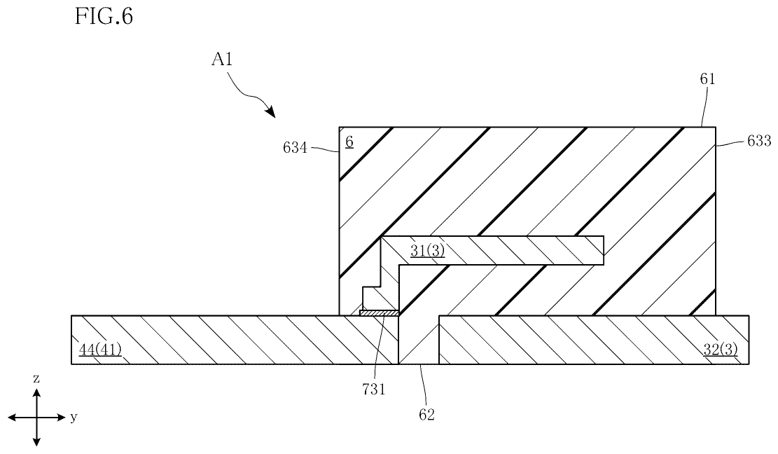

As shown in FIG. 5, the first conductive plate 31 is provided between the first semiconductor chip 1 and the second semiconductor chip 2 in the thickness direction z. As shown in FIG. 6, the first conductive plate 31 is partially bent and connected to one (an output terminal 44 described below) of the power terminals 41. As shown in FIGS. 3 and 4, the first conductive plate 31 does not overlap with the first gate electrode 13 of the first semiconductor chip 1 in plan view.

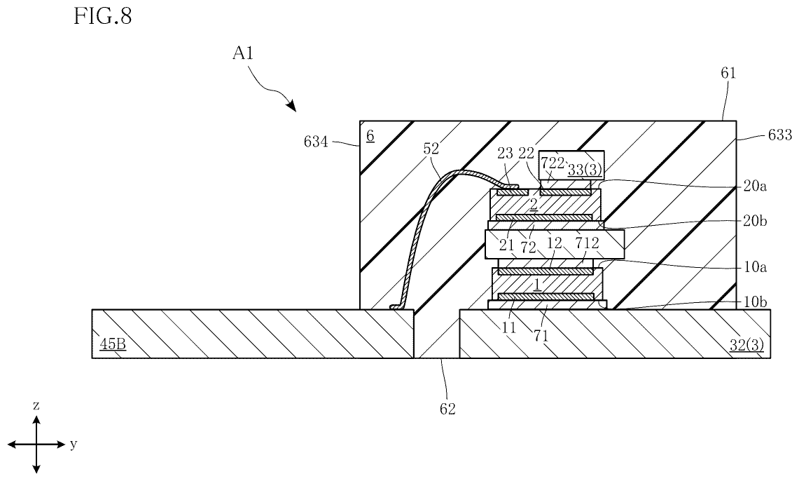

As shown in FIGS. 5, 7, and 8, the first emitter electrode 12 of the first semiconductor chip 1 is bonded to the first conductive plate 31 via a conductive bonding member 712. Furthermore, as shown in FIG. 5, the anode electrode 191 of the first diode chip 19 is bonded to the first conductive plate 31 via a conductive bonding member 719. Furthermore, as shown in FIGS. 5 and 8, the second collector electrode 21 of the second semiconductor chip 2 and the cathode electrode 292 of the second diode chip 29 are bonded to the first conductive plate 31 via a conductive bonding member 72. Unlike this configuration, each of the second collector electrode 21 and the cathode electrode 292 may be bonded to the first conductive plate 31 by a different conductive bonding member instead of the common conductive bonding member 72. The first conductive plate 31 is electrically connected to the first emitter electrode 12, the anode electrode 191, the second collector electrode 21, and the cathode electrode 292. In other words, the following elements are electrically connected to each other via the first conductive plate 31. Firstly, the first emitter electrode 12 and the anode electrode 191 are electrically connected to each other. Secondly, the second collector electrode 21 and the cathode electrode 292 are electrically connected to each other. Thirdly, the first emitter electrode 12 and the second collector electrode 21 are electrically connected to each other.

As shown in FIG. 5, the second conductive plate 32 is arranged below the first conductive plate 31 in the thickness direction z with the first semiconductor chip 1 and the first diode chip 19 therebetween. Accordingly, as shown in FIG. 5, the first semiconductor chip 1 and the first diode chip 19 are positioned between the first conductive plate 31 and the second conductive plate 32 in the thickness direction z. The dimension of the second conductive plate 32 in the thickness direction z is larger than each of the dimension of the first conductive plate 31 in the thickness direction z and the dimension of the third conductive plate 33 in the thickness direction z. The second conductive plate 32 is connected to one (a first input terminal 42 described below) of the power terminals 41. In the example shown in FIGS. 5 to 9, the lower surface (the surface facing downward in the thickness direction z) of the second conductive plate 32 is exposed from the sealing resin 6. Unlike this example, the lower surface of the second conductive plate 32 maybe covered with the sealing resin 6. However, when the lower surface of the second conductive plate 32 is exposed from the sealing resin 6, the heat generated from the first semiconductor chip 1 and the second semiconductor chip 2 is released via the second conductive plate 32, thus allowing an improvement of the heat dissipation of the semiconductor device A1.

As shown in FIGS. 5, 7, and 8, the first collector electrode 11 and the cathode electrode 192 are bonded to the second conductive plate 32 via a conductive bonding member 71. Unlike this configuration, each of the first collector electrode 11 and the cathode electrode 192 may be bonded to the second conductive plate 32 by a different conductive bonding member instead of the common conductive bonding member 71. The second conductive plate 32 is electrically connected to the first collector electrode 11 and the cathode electrode 192. In other words, the first collector electrode 11 and the cathode electrode 192 are electrically connected to each other via the second conductive plate 32.

As shown in FIG. 5, the third conductive plate 33 is arranged above the first conductive plate 31 in the thickness direction z with the second semiconductor chip 2 and the second diode chip 29 therebetween. Accordingly, as shown in FIG. 5, the second semiconductor chip 2 and the second diode chip 29 are positioned between the first conductive plate 31 and the third conductive plate 33 in the thickness direction z. As shown in FIGS. 2 and 3, the third conductive plate 33 does not overlap with the second gate electrode 23 of the second semiconductor chip 2 in plan view. In the semiconductor device A1, the third conductive plate 33 also does not overlap with the first gate electrode 13 of the first semiconductor chip 1 in plan view. If there is a clearance sufficient for placing the first connecting member 51 between the third conductive plate 33 and the first gate electrode 13 in the thickness direction z, the third conductive plate 33 may overlap with the first gate electrode 13 in plan view.

As shown in FIGS. 5 and 8, the second emitter electrode 22 is bonded to the third conductive plate 33 via a conductive bonding member 722. Furthermore, as shown in FIG. 5, the anode electrode 291 is bonded to the third conductive plate 33 via a conductive bonding member 729. The third conductive plate 33 is electrically connected to the second emitter electrode 22 via the conductive bonding member 722, and is electrically connected to the anode electrode 291 via the conductive bonding member 729. The third conductive plate 33 is electrically connected to the second emitter electrode 22 and the anode electrode 291. In other words, the second emitter electrode 22 and the anode electrode 291 are electrically connected to each other via the third conductive plate 33.

Each of the power terminals 41 is electrically connected to at least one of the first semiconductor chip 1 and the second semiconductor chip 2. Each of the power terminals 41 is made of a metal plate. The power terminals 41 are made of copper or a copper alloy. The constituent material of each power terminal 41 is not limited to copper or a copper alloy, and may be another metal material. As shown in FIGS. 1 to 4, the power terminals 41 include a first input terminal 42, a second input terminal 43, and an output terminal 44.

The first input terminal 42 and the second input terminal 43 are connected to an external power supply, from which a first voltage is applied. The first voltage applied to the first input terminal 42 and the second input terminal 43 is converted into a second voltage by driving the first semiconductor chip 1 and the second semiconductor chip 2. The second voltage thus converted is outputted from the output terminal 44. In the present embodiment, the external power supply is a DC power supply, and a DC voltage is applied between the first input terminal 42 and the second input terminal 43. At this point, the first input terminal 42 is a P terminal connected to the positive electrode of the DC power supply, for example, and the second input terminal 43 is an N terminal connected to the negative electrode of the DC power supply, for example. The DC voltage is then converted into an AC voltage by the switching operations of the first semiconductor chip 1 and the second semiconductor chip 2. The AC voltage thus converted is outputted from the output terminal 44. In other words, in the semiconductor device A1, the first voltage is the DC voltage outputted from the DC power supply, and the second voltage is the AC voltage. The polarities of the first input terminal 42 and the second input terminal 43 maybe the other way around. That is, the first input terminal 42 maybe the N terminal, and the second input terminal 43 maybe the P terminal. In this case, the wiring inside the package may be changed appropriately according to the change of the polarities of the terminals.

As shown in FIG. 10, the first input terminal 42 is electrically connected to a first end of the bridge B. The first input terminal 42 includes a portion covered with the sealing resin 6 and a portion exposed from the sealing resin 6. The portion of the first input terminal 42 covered with the sealing resin 6 is connected to the second conductive plate 32. Although the first input terminal 42 of the semiconductor device A1 is integrally formed with the second conductive plate 32, it may be joined with the second conductive plate 32 by conductive bonding. The power terminals 41 are electrically connected to the second conductive plate 32. Since the second conductive plate 32 is electrically connected to the first collector electrode 11 of the first semiconductor chip 1 and the cathode electrode 192 of the first diode chip 19, the power terminals 41 are electrically connected to the first collector electrode 11 and the cathode electrode 192 via the second conductive plate 32.

As shown in FIG. 10, the second input terminal 43 is electrically connected to a second end of the bridge B. The second input terminal 43 includes a portion covered with the sealing resin 6 and a portion exposed from the sealing resin 6. The portion of the second input terminal 43 covered with the sealing resin 6 is bonded to the third conductive plate 33 via a conductive bonding member 733. The second input terminal 43 is electrically connected to the third conductive plate 33 via the conductive bonding member 733. Since the third conductive plate 33 is electrically connected to the second emitter electrode 22 of the second semiconductor chip 2 and the anode electrode 291 of the second diode chip 29, the second input terminal 43 is electrically connected to the second emitter electrode 22 and the anode electrode 291 via the third conductive plate 33.

As shown in FIG. 10, the output terminal 44 is electrically connected to a connecting point P1 between the first semiconductor chip 1 and the second semiconductor chip 2. The output terminal 44 includes a portion covered with the sealing resin 6 and a portion exposed from the sealing resin 6. The portion of the output terminal 44 covered with the sealing resin 6 is bonded to the first conductive plate 31 via a conductive bonding member 731. The output terminal 44 is electrically connected to the first conductive plate 31 via the conductive bonding member 731. Since the first conductive plate 31 is electrically connected to the first emitter electrode 12 of the first semiconductor chip 1, the anode electrode 191 of the first diode chip 19, the second collector electrode 21 of the second semiconductor chip 2, and the cathode electrode 292 of the second diode chip 29, the output terminal 44 is electrically connected to the first emitter electrode 12, the anode electrode 191, the second collector electrode 21, and the cathode electrode 292 via the first conductive plate 31.

As with the power terminals 41, the first signal terminal 45A and the second signal terminal 45B are metal plates. The first signal terminal 45A and the second signal terminal 45B are made of copper or a copper alloy. The constituent material of each of the first signal terminal 45A and the second signal terminal 45B is not limited to copper or a copper alloy and may be another metal material.

The first signal terminal 45A is electrically connected to the first gate electrode 13 of the first semiconductor chip 1. The first signal terminal 45A receives a first gate signal (gate voltage) that controls the switching operation of the first semiconductor chip 1. The first signal terminal 45A includes a portion covered with the sealing resin 6 and a portion exposed from the sealing resin 6. The portion of the first signal terminal 45A covered with the sealing resin 6 is connected to the first connecting member 51. The portion of the first signal terminal 45A exposed from the sealing resin 6 is connected to an external control terminal (e.g., a gate driver), from which a first gate signal is inputted. The first signal terminal 45A is spaced apart from the conductive member 3, and is not electrically connected to the conductive member 3.

The second signal terminal 45B is electrically connected to the second gate electrode 23 of the second semiconductor chip 2. The second signal terminal 45B receives a second gate signal (gate voltage) that controls the switching operation of the second semiconductor chip 2. The second signal terminal 45B includes a portion covered with the sealing resin 6 and a portion exposed from the sealing resin 6. The portion of the second signal terminal 45B covered with the sealing resin 6 is connected to the second connecting member 52. The portion of the second signal terminal 45B exposed from the sealing resin 6 is connected to an external control terminal (e.g., a gate driver), from which a second gate signal is inputted. The second signal terminal 45B is spaced apart from the conductive member 3, and is not electrically connected to the conductive member 3.

As shown in FIGS. 1 to 4, the power terminals 41 (the first input terminal 42, the second input terminal 43, and the output terminal 44), the first signal terminal 45A, and the second signal terminal 45B extend in the second direction y. Unlike the example shown in FIGS. 1 to 4, the tip (the distal end far from the sealing resin 6 in the second direction y) of each of the power terminals 41, the first signal terminal 45A, and the second signal terminal 45B may be tapered. As shown in FIGS. 1 to 4, the power terminals 41, the first signal terminal 45A, and the second signal terminal 45B are arranged in parallel in plan view.

In the example shown in FIGS. 1 to 4, the first input terminal 42 is positioned between the second input terminal 43 and the output terminal 44 in the first direction x, the second input terminal 43 is positioned on the first side in the first direction x with respect to the first input terminal 42, and the output terminal 44 is positioned on the second side in the first direction x with respect to the first input terminal 42. The first signal terminal 45A is positioned between the output terminal 44 and the first input terminal 42 in the first direction x, and the second signal terminal 45B is positioned between the first input terminal 42 and the second input terminal 43 in the first direction x. The arrangement of the power terminals 41, the first signal terminal 45A, and the second signal terminal 45B shown in FIGS. 1 to 4 is merely an example, and can be changed as appropriate. Note that the shape of the conductive member 3 (the first conductive plate 31, the second conductive plate 32, and the third conductive plate 33) and the arrangement of each chip (the first semiconductor chip 1, the first diode chip 19, the second semiconductor chip 2, and the second diode chip 29) are changed as appropriate according to the positional relationship between the power terminals 41, the first signal terminal 45A, and the second signal terminal 45B.

Each of the first connecting member 51 and the second connecting member 52 electrically connects two elements spaced apart from each other. As shown in FIGS. 2 to 4, 7 and 8, the first connecting member 51 and the second connecting member 52 are bonding wires, for example. The first connecting member 51 and the second connecting member 52 maybe other plate-like metal members rather than bonding wires. The constituent material of each of the first connecting member 51 and the second connecting member 52 is either gold, aluminum, or copper.

As shown in FIGS. 2 to 4 and 7, the first connecting member 51 is bonded to the first gate electrode 13 and the first signal terminal 45A to electrically connect them. With this configuration, the first signal terminal 45A and the first gate electrode 13 are electrically connected to each other via the first connecting member 51. Although the number of first connecting members 51 in the example shown in FIGS. 2 to 4 and 7 is one, it may be two or more.

As shown in FIGS. 2, 3, and 8, the second connecting member 52 is bonded to the second gate electrode 23 and the second signal terminal 45B to electrically connect them. With this configuration, the second signal terminal 45B and the second gate electrode 23 are electrically connected to each other via the second connecting member 52. Although the number of second connecting members 52 in the example shown in FIGS. 2, 3 and 8 is one, it may be two or more.

The sealing resin 6 covers the first semiconductor chip 1, the second semiconductor chip 2, a portion of the conductive member 3, a portion of each power terminal 41, a portion of the first signal terminal 45A, a portion of the second signal terminal 45B, the first connecting member 51, and the second connecting member 52. The sealing resin 6 is made of an insulating resin material such as an epoxy resin, for example. As shown in FIGS. 1, 2, and 5 to 9, the sealing resin 6 has a resin obverse surface 61, a resin reverse surface 62, and a plurality of resin side surfaces 631 to 634.

As shown in FIGS. 5 to 9, the resin obverse surface 61 and the resin reverse surface 62 are spaced apart from each other in the thickness direction z. The resin obverse surface 61 faces upward in the thickness direction z, and the resin reverse surface 62 faces downward in the thickness direction z.

As shown in FIGS. 5 to 9, the resin side surfaces 631 to 634 are connected to the resin obverse surface 61 and the resin reverse surface 62, and are provided therebetween in the thickness direction z. As shown in FIGS. 1, 2, and 5, the resin side surface 631 and the resin side surface 632 are spaced apart from each other in the first direction x. The resin side surface 631 faces the first side in the first direction x, and the resin side surface 632 faces the second side in the first direction x. As shown in FIGS. 1, 2, and 6 to 9, the resin side surface 633 and the resin side surface 634 are spaced apart from each other in the second direction y. The resin side surface 633 faces the first side in the second direction y, and the resin side surface 634 faces the second side in the second direction y.

As shown in FIGS. 2, and 6 to 9, in the semiconductor device A1, the power terminals 41, the first signal terminal 45A, and the second signal terminal 45B are exposed from the resin side surface 634, and protrude from the resin side surface 634 in the second direction y. In other words, all of the power terminals 41, the first signal terminal 45A, and the second signal terminal 45B are exposed from the resin side surface 634, which is one of the resin side surfaces 631 to 634. In the semiconductor device A1, the resin side surface 634 is an example of a “first resin side surface”.

The advantages of the semiconductor device A1 are as follows.

The semiconductor device A1 includes the first semiconductor chip 1, the second semiconductor chip 2, and the conductive member 3. The conductive member 3 includes the first conductive plate 31 electrically connected to the first semiconductor chip 1 and the second semiconductor chip 2. The first conductive plate 31 is provided between the first semiconductor chip 1 and the second semiconductor chip 2 in the thickness direction z. According to this configuration, the first semiconductor chip 1 and the second semiconductor chip 2 are electrically connected to each other by the first conductive plate 31 interposed therebetween. As described above, the semiconductor device A1 does not include a substrate between the first semiconductor chip 1 and the second semiconductor chip 2, thereby reducing the distance between the first semiconductor chip 1 and the second semiconductor chip 2 as much as possible. Accordingly, the semiconductor device A1 can be configured with the first semiconductor chip 1 and the second semiconductor chip 2 arranged in multiple stages while reducing the height of the semiconductor device A1.

In the semiconductor device A1, the first emitter electrode 12 of the first semiconductor chip 1 and the second collector electrode 21 of the second semiconductor chip 2 are connected at a position where the first emitter electrode 12 and the second collector electrode 21 partially face each other via the first conductive plate 31. Thus, the first emitter electrode 12 and the second collector electrode 21 are connected by a wire having a length equivalent to the dimension of the first conductive plate 31 in the thickness direction z and having a cross-sectional area equivalent to the area in which the first emitter electrode 12 and the second collector electrode 21 overlap with each other in plan view. This makes it possible to suppress the wiring resistance and wiring inductance generated in the wire connecting the first emitter electrode 12 and the second collector electrode 21.

In the semiconductor device A1, each of the first conductive plate 31 and the third conductive plate 33 has a dimension smaller than the dimension of the second conductive plate 32 in the thickness direction z. The semiconductor device A1 is configured such that the first semiconductor chip 1 and the second semiconductor chip 2 are arranged in multiple stages. Accordingly, in the manufacturing of the semiconductor device A1, the first semiconductor chip 1, the first conductive plate 31, the second semiconductor chip 2, and the third conductive plate 33 are joined in this order on the second conductive plate 32. At this point, the first semiconductor chip 1 is subjected to stress when the first conductive plate 31 is joined thereto, and the second semiconductor chip 2 is subjected to stress when the third conductive plate 33 is bonded thereto. Thus, the stress applied to each of the first semiconductor chip 1 and the second semiconductor chip 2 can be reduced by setting the dimension of each of the first conductive plate 31 and the third conductive plate 33 in the thickness direction z to be smaller than the dimension of the second conductive plate 32.

The first gate electrode 13 of the semiconductor device A1 is arranged at a corner of the first obverse surface 10a on the second side in the second direction y. The first signal terminal 45A is arranged on the second side in the second direction y with respect to the first semiconductor chip 1. According to this configuration, the first gate electrode 13 is arranged near the first signal terminal 45A. As such, the length of the first connecting member 51 can be shortened. This makes it possible to reduce the resistance component of the first connecting member 51. Furthermore, when the first gate electrode 13 is arranged near the first signal terminal 45A, there is no need of increasing the loop height of the first connecting member 51 to avoid other elements when the first connecting member 51 is connected. Since the semiconductor device A1 can suppress the loop height of the first connecting member 51, it is possible to suppress an increase of the dimension in the thickness direction z of the sealing resin 6 covering the first connecting member 51. In other words, the semiconductor device A1 is preferable for reducing the height of the semiconductor device A1. This also applies to the second signal terminal 45B.

### Second Embodiment

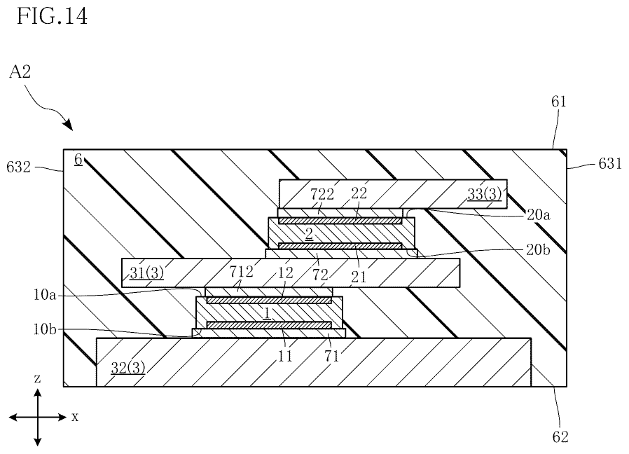

FIGS. 11 to 15 show a semiconductor device A2 according to a second embodiment. The semiconductor device A2 is different from the semiconductor device A1 in that the first semiconductor chip 1 and the second semiconductor chip 2 are reverse-conducting IGBTs.

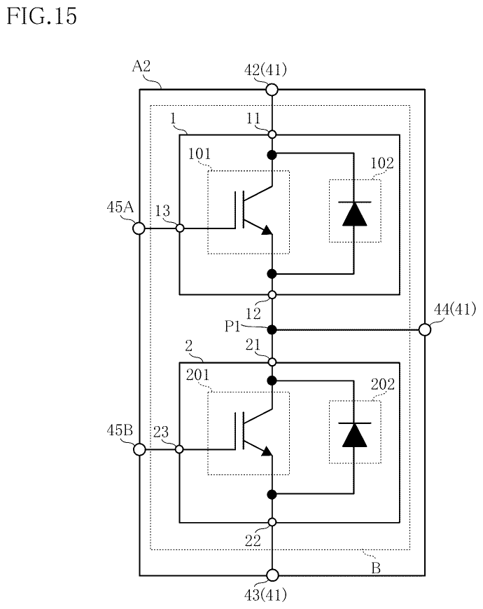

The first semiconductor chip 1 of the semiconductor device A2 is provided by integrating the first semiconductor chip 1 and the first diode chip 19 of the semiconductor device A1 into one chip. As shown in FIG. 15, the first semiconductor chip 1 of the semiconductor device A2 has an IGBT region 101 that operates as an IGBT and a diode region 102 that operates as a diode. As shown in FIG. 15, the IGBT region 101 and the diode region 102 are electrically connected in reverse parallel. In plan view, the percentage ratio of placement of the diode region 102 to the first semiconductor chip 1 is in the range of 5% to 40%, both inclusive. The performance of the first semiconductor chip 1 (the switching performance in the IGBT region 101 and the diode performance in the diode region 102) can be changed as appropriate by changing the relative ratio between the IGBT region 101 and the diode region 102. For example, the performance of suppressing the flow of a reverse current through the IGBT region 101 can be enhanced by increasing the relative percentage of the diode region 102. On the other hand, increasing the relative percentage of the IGBT region 101 can increase the allowable current in the IGBT region 101.

The second semiconductor chip 2 of the semiconductor device A2 is provided by integrating the second semiconductor chip 2 and the second diode chip 29 of the semiconductor device A1 into one chip. As shown in FIG. 15, the second semiconductor chip 2 of the semiconductor device A2 has an IGBT region 201 that operates as an IGBT and a diode region 202 that operates as a diode. As shown in FIG. 15, the IGBT region 201 and the diode region 202 are electrically connected in reverse parallel. In plan view, the percentage ratio of placement of the diode region 202 to the second semiconductor chip 2 is in the range of 5% to 40%, both inclusive. As with the first semiconductor chip 1, the performance of the second semiconductor chip 2 (the switching performance in the IGBT region 201 and the diode performance in the diode region 202) can be changed as appropriate by changing the relative ratio between the IGBT region 201 and the diode region 202.

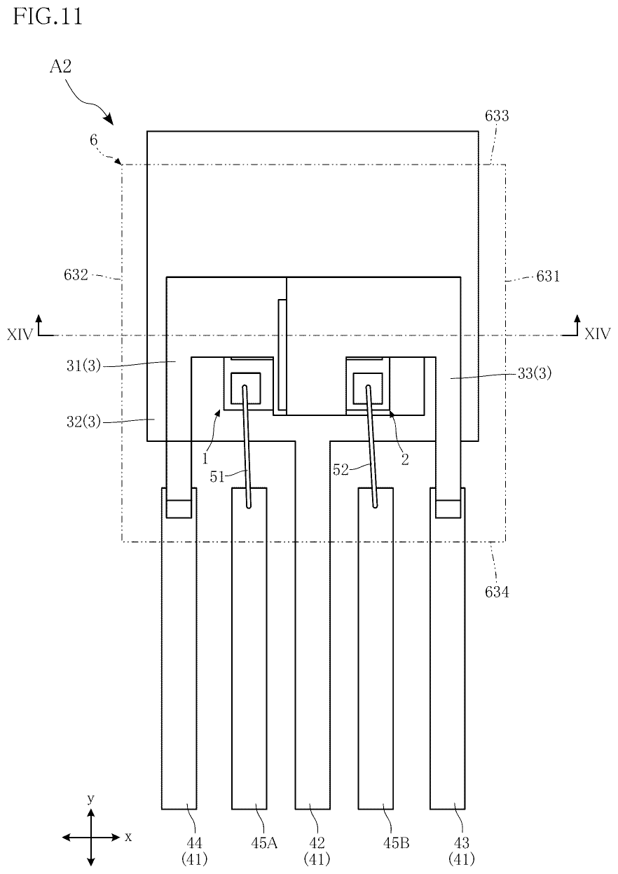

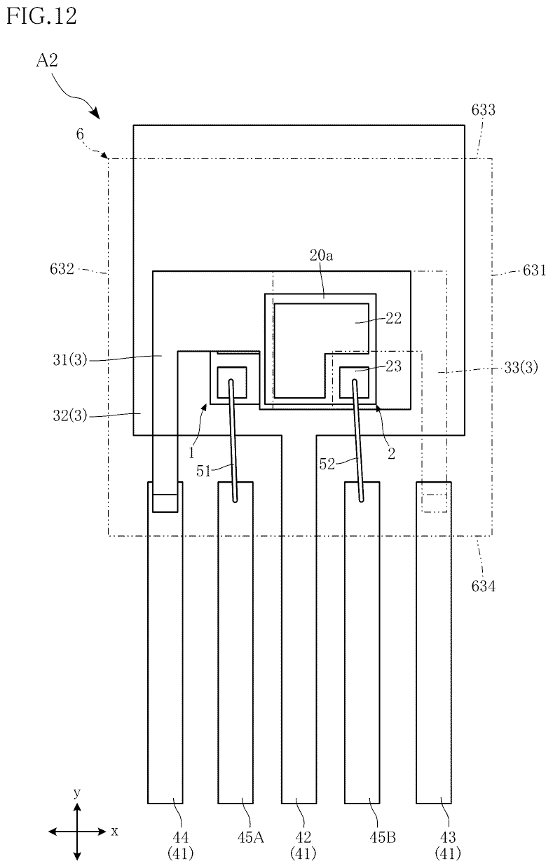

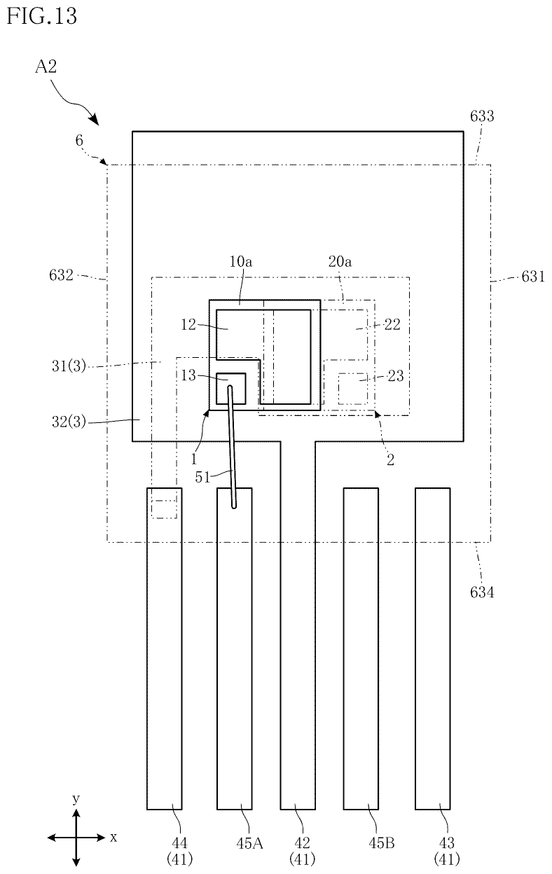

As shown in FIG. 13, the first gate electrode 13 of the semiconductor device A2 is arranged at the corner portion (near the lower left corner in FIG. 13) of the first obverse surface 10a on the second side in the first direction x and on the second side in the second direction y. Furthermore, as shown in FIG. 12, the second gate electrode 23 is arranged at the corner portion (near the lower right corner in FIG. 12) of the second obverse surface 20a on the first side in the first direction x and on the second side in the second direction y.

As shown in FIGS. 11 to 14, the plan-view shape of the conductive member 3 (the first conductive plate 31 and the third conductive plate 33) of the semiconductor device A2 is changed from the plan-view shape of the conductive member 3 (the first conductive plate 31 and the third conductive plate 33) of the semiconductor device A1 according to the respective positions of the first gate electrode 13 of the first semiconductor chip 1 and the second gate electrode 23 of the second semiconductor chip 2. However, as with the semiconductor device A1, the shape of the first conductive plate 31 of the semiconductor device A2 does not overlap with the first gate electrode 13 in plan view, and the shape of the third conductive plate 33 of the semiconductor device A2 does not overlap with the first gate electrode 13 and the second gate electrode 23 in plan view.

The semiconductor device A2 is similar to the semiconductor device A1 in that the first conductive plate 31 is positioned between the first semiconductor chip 1 and the second semiconductor chip 2 in the thickness direction z, and the first semiconductor chip 1 and the second semiconductor chip 2 are electrically connected to each other via the first conductive plate 31. Accordingly, as with the semiconductor device A1, the semiconductor device A2 can be configured with the first semiconductor chip 1 and the second semiconductor chip 2 arranged in multiple stages while reducing the height of the semiconductor device A2. Furthermore, the semiconductor device A2 has advantages similar to the semiconductor device A1 owing to its common configuration with the semiconductor device A1.

In the semiconductor device A2, the first semiconductor chip 1 and the second semiconductor chip 2 are reverse-conducting IGBTs. Unlike the semiconductor device A1, this configuration eliminates the need of providing the first diode chip 19 for the first semiconductor chip 1 and the need of providing the second diode chip 29 for the second semiconductor chip 2. Accordingly, the semiconductor device A2 reduces the limitations on the shape and arrangement of the first conductive plate 31 and the shape and arrangement of the third conductive plate 33. In other words, the semiconductor device A2 can be more easily designed than the semiconductor device A1. Furthermore, the semiconductor device A2 does not need to include the first diode chip 19 and the second diode chip 29, and therefore does not need to match the height of the first semiconductor chip 1 to that of the first diode chip 19 and to match the height of the second semiconductor chip 2 to that of the second diode chip 29. In other words, the semiconductor device A2 can be more easily manufactured than the semiconductor device A1.

In each of the semiconductor devices A1 and A2 according to the first embodiment and the second embodiment, the first input terminal 42 and the output terminal 44 maybe arranged the other way around. In this case, the separation distance between the first input terminal 42 and the second input terminal 43 in the first direction x will be large as compared to the example shown in FIGS. 1 to 4. Among the elements of the semiconductor device according to the present disclosure, the first input terminal 42 and the second input terminal 43 have a relatively large potential difference therebetween. Thus, increasing the distance between the first input terminal 42 and the second input terminal 43 can suppress an unintentional short circuit between the first input terminal 42 and the second input terminal 43.

### Third Embodiment

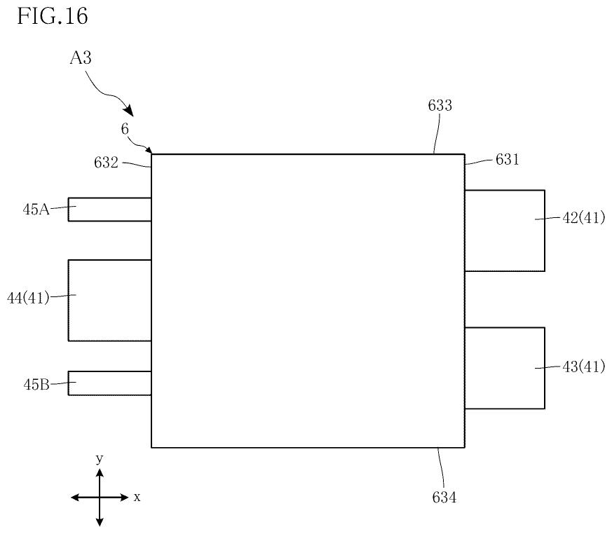

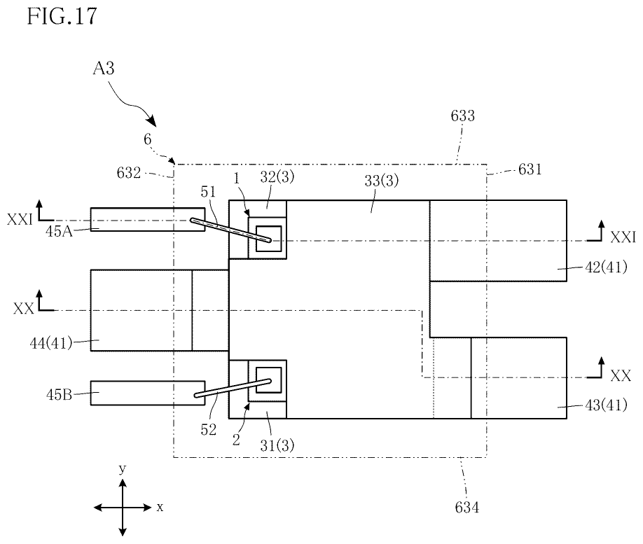

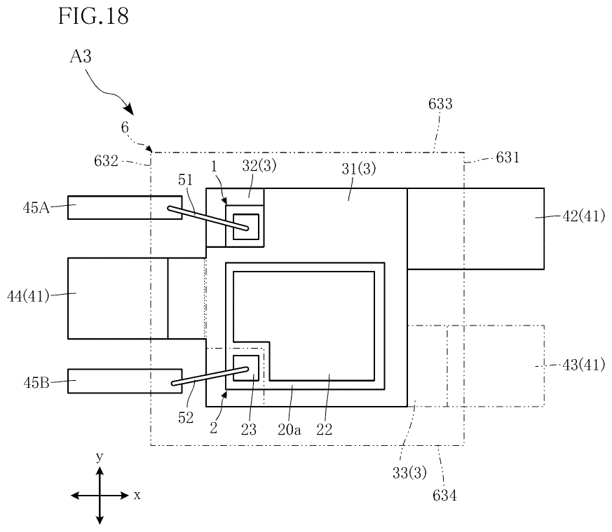

FIGS. 16 to 21 show a semiconductor device A3 according to a third embodiment. Unlike each of the semiconductor devices A1 and A2, the semiconductor device A3 is surface-mounted on the circuit board of an electric device or the like.

In the example given below, the semiconductor device A3 is similar to the semiconductor device A2 in that the first semiconductor chip 1 and the second semiconductor chip 2 are reverse-conducting IGBTs. Accordingly, the example of the circuit configuration of the semiconductor device A3 is the same as that of the semiconductor device A2 shown in FIG. 15. Unlike this example, the semiconductor device A3 may include the first semiconductor chip 1, the first diode chip 19, the second semiconductor chip 2, and the second diode chip 29. In other words, the example of the circuit configuration of the semiconductor device A3 may be the same as that of the semiconductor device A1 shown in FIG. 10.

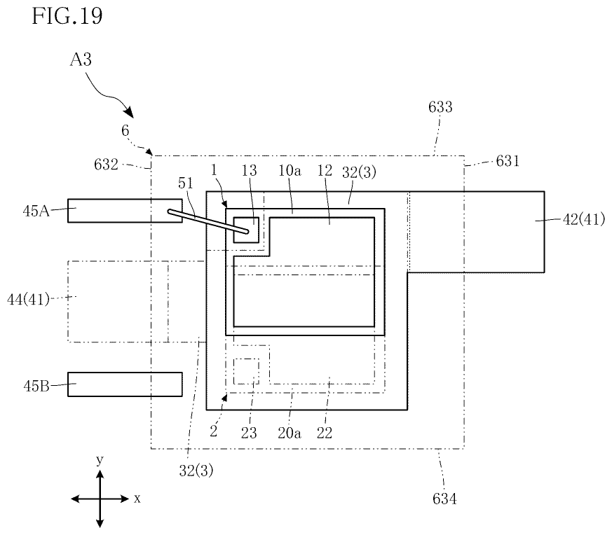

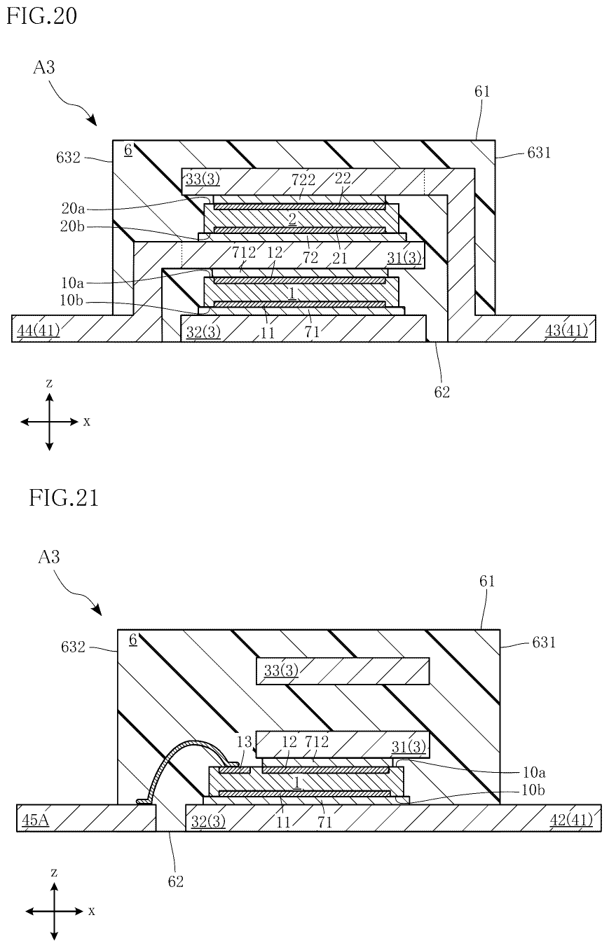

As shown in FIG. 21, the first input terminal 42 of the semiconductor device A3 is integrally formed with the second conductive plate 32, as with the semiconductor devices A1 and A2. The second input terminal 43 is integrally formed with the third conductive plate 33, as shown in FIG. 20. As shown in FIG. 20, the output terminal 44 is integrally formed with the first conductive plate 31. As shown in FIG. 20, each of the second input terminal 43 and the output terminal 44 has an S-shape in cross section.

In the semiconductor device A3, the first input terminal 42 and the second input terminal 43 are exposed from the resin side surface 631, and protrude from the resin side surface 631 to the first side in the first direction x. Furthermore, in the semiconductor device A3, the output terminal 44, the first signal terminal 45A, and the second signal terminal 45B are exposed from the resin side surface 632, and protrude from the resin side surface 632 to the second side in the first direction x. Thus, in the semiconductor device A3, the first input terminal 42 and the second input terminal 43 are exposed from the resin side surface 631, which is one of the resin side surfaces 631 to 634 and different from the resin side surface 632 from which the first signal terminal 45A and the second signal terminal 45B are exposed. In the semiconductor device A3, the resin side surface 632 is an example of the “first resin side surface”.

In the example shown in FIGS. 16 to 18, the power terminals 41 (the first input terminal 42, the second input terminal 43, and the output terminal 44), the first signal terminal 45A, and the second signal terminal 45B have the following positional relationship. Firstly, the first input terminal 42 and the second input terminal 43 are adjacent to each other in the second direction y, and the first input terminal 42 is offset from the second input terminal 43 to the first side in the second direction y. Secondly, the output terminal 44 is arranged between the first signal terminal 45A and the second signal terminal 45B. Thirdly, the first signal terminal 45A and the second signal terminal 45B are arranged on the side opposite from the first input terminal 42 and the second input terminal 43 with the first semiconductor chip 1 and the second semiconductor chip 2 therebetween.

In the semiconductor device A3, the lower surface (the surface facing downward in the thickness direction z) of the second conductive plate 32 is exposed from the sealing resin 6, as with the semiconductor devices A1 and A2. In the example shown in FIGS. 20 and 21, the second conductive plate 32 has the same (or substantially the same) dimension as that of each of the first conductive plate 31 and the third conductive plate 33 in the thickness direction z. Unlike this example, the dimension of the second conductive plate 32 in the thickness direction z may be larger than that of each of the first conductive plate 31 and the third conductive plate 33, as with the semiconductor devices A1 and A2.

The semiconductor device A3 is similar to the semiconductor devices A1 and A2 in that the first conductive plate 31 is positioned between the first semiconductor chip 1 and the second semiconductor chip 2 in the thickness direction z, and the first semiconductor chip 1 and the second semiconductor chip 2 are electrically connected to each other via the first conductive plate 31. Accordingly, as with the semiconductor devices A1 and A2, the semiconductor device A3 can be configured with the first semiconductor chip 1 and the second semiconductor chip 2 arranged in multiple stages while reducing the height of the semiconductor device A3. Furthermore, the semiconductor device A3 has advantages similar to the semiconductor devices A1 and A2 owing to its common configuration with the semiconductor devices A1 and A2.

In the semiconductor device A3, the first input terminal 42 and the second input terminal 43 are aligned in the second direction y. According to this configuration, the mutual inductance between the inductance caused by the current flowing through the first input terminal 42 and the inductance caused by the current flowing through the second input terminal 43 reduces the internal inductance in the semiconductor device A3. In other words, the semiconductor device according to the present disclosure can reduce the internal inductance by arranging the first input terminal 42 and the second input terminal 43 to be adjacent to each other.

### Fourth Embodiment

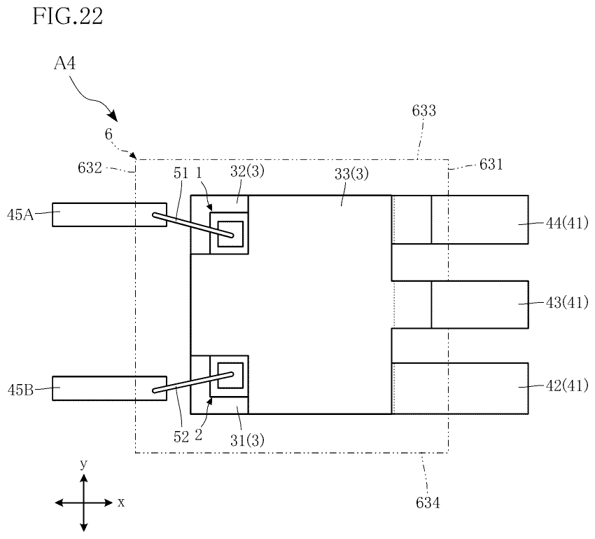

FIGS. 22 to 24 show a semiconductor device A4 according to a fourth embodiment. As shown in FIGS. 22 to 24, the semiconductor device A4 is different from the semiconductor device A3 in the arrangement of the power terminals 41.

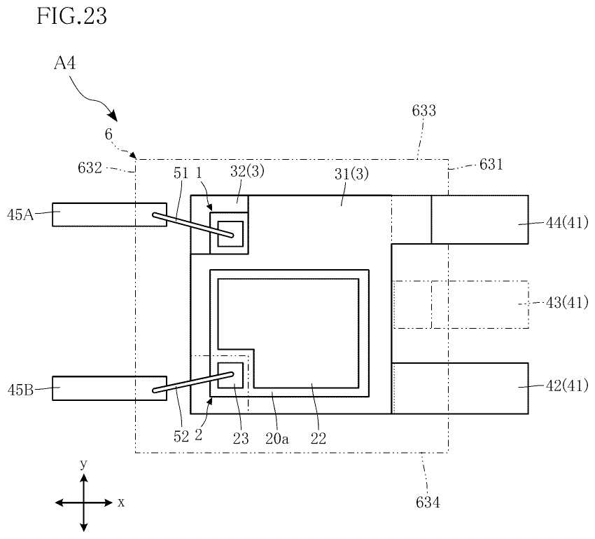

In the example shown in FIGS. 22 and 23, the power terminals 41 (the first input terminal 42, the second input terminal 43, and the output terminal 44) are exposed from the resin side surface 631, and protrude from the resin side surface 631 to the first side in the first direction x. Furthermore, in the semiconductor device A4, the first signal terminal 45A and the second signal terminal 45B are exposed from the resin side surface 632, and protrude from the resin side surface 632 to the second side in the first direction x. Thus, in the semiconductor device A4, the power terminals 41 (the first input terminal 42, the second input terminal 43, and the output terminal 44) are all exposed from the resin side surface 631, which is one of the resin side surfaces 631 to 634 and different from the resin side surface 632 from which the first signal terminal 45A and the second signal terminal 45B are exposed. In the semiconductor device A4, the resin side surface 632 is an example of the “first resin side surface”.

In the example shown in FIGS. 22 and 23, the power terminals 41 (the first input terminal 42, the second input terminal 43, and the output terminal 44), the first signal terminal 45A, and the second signal terminal 45B have the following positional relationship. Firstly, the first input terminal 42, the second input terminal 43, and the output terminal 44 are arranged in this order from the second side in the second direction y to the first side in the second direction y. Note that the positional relationship between the first input terminal 42, the second input terminal 43, and the output terminal 44 is not limited to the illustrated example, and can be changed as appropriate. For example, the output terminal 44 maybe arranged between the first input terminal 42 and the second input terminal 43 to suppress an unintentional short circuit between the first input terminal 42 and the second input terminal 43. Secondly, the first signal terminal 45A and the second signal terminal 45B are arranged on the side opposite from the first input terminal 42 and the second input terminal 43 with the first semiconductor chip 1 and the second semiconductor chip 2 therebetween.

The semiconductor device A4 is similar to the semiconductor devices A1 to A3 in that the first conductive plate 31 is positioned between the first semiconductor chip 1 and the second semiconductor chip 2 in the thickness direction z, and the first semiconductor chip 1 and the second semiconductor chip 2 are electrically connected to each other via the first conductive plate 31. Accordingly, as with the semiconductor devices A1 to A3, the semiconductor device A4 can be configured with the first semiconductor chip 1 and the second semiconductor chip 2 arranged in multiple stages while reducing the height of the semiconductor device A4. Furthermore, the semiconductor device A4 has advantages similar to the semiconductor devices A1 to A3 owing to its common configuration with the semiconductor devices A1 to A3.

In the semiconductor device A4, the power terminals 41 are exposed from the resin side surface 631, and the first signal terminal 45A and the second signal terminal 45B are exposed from the resin side surface 632. According to this configuration, the power terminals 41 can be arranged separately from the first signal terminal 45A and the second signal terminal 45B in the first direction x. When the semiconductor device A4 is energized, a magnetic field is generated by the current flowing through each of the power terminals 41. The magnetic field may cause noise to be superimposed on the gate signal inputted to each of the first signal terminal 45A and the second signal terminal 45B. However, the semiconductor device A4 can increase the distance from each of the first signal terminal 45A and the second signal terminal 45B to each of the power terminals 41, thereby suppressing the effect of the magnetic field generated by the energization of the power terminals 41. In other words, the semiconductor device A4 can suppress the superimposition of noise on the gate signals inputted to the first signal terminal 45A and the second signal terminal 45B. The suppression of noise as described above can reduce malfunctions of the first semiconductor chip 1 and the second semiconductor chip 2.

In the third embodiment and the fourth embodiment, the power terminals 41, the first signal terminal 45A, and the second signal terminal 45B may be exposed from any of the resin side surfaces 631 to 634. For example, the first signal terminal 45A and the second signal terminal 45B may be exposed from two different resin side surfaces among the resin side surfaces 631 to 634. For example, the power terminals 41, the first signal terminal 45A, and the second signal terminal 45B may be exposed from three or more resin side surfaces among the resin side surfaces 631 to 634.

In the third embodiment and the fourth embodiment, the power terminals 41, the first signal terminal 45A, and the second signal terminal 45B may be flush with one of the resin side surfaces 631 to 634, rather than protruding from one of the resin side surfaces 631 to 634. In other words, the semiconductor device according to the present disclosure may have a non-lead package structure.

In the first embodiment to the fourth embodiment, the positional relationship between the power terminals 41 (the first input terminal 42, the second input terminal 43, and the output terminal 44), the first signal terminal 45A, and the second signal terminal 45B is not limited to the illustrated example. The positional relationship between the power terminals 41, the first signal terminal 45A, and the second signal terminal 45B can be changed appropriately according to the electrical relationship therebetween (e.g., a potential difference, the magnitude of current, the direction of current, and the type of a transmission signal). For example, as described above, the first input terminal 42 and the second input terminal 43 maybe adjacent to each other to reduce the internal inductance. Furthermore, the distance (e.g., creepage distance) between the first input terminal 42 and the second input terminal 43 maybe increased to suppress an unintentional short circuit. Furthermore, unlike the electrical relationship described above, the positional relationship of the terminals may be changed appropriately according to the wiring of the circuit board of an electric device to which the semiconductor device is mounted.

The semiconductor devices A1 and A2 according to the first embodiment and the second embodiment have been described with an example where the first conductive plate 31 and the output terminal 44 are bonded to each other with the conductive bonding member 731, and the third conductive plate 33 and the second input terminal 43 are bonded to each other with the conductive bonding member 733. However, unlike this example, these elements may be integrally formed in the same manner as in the semiconductor devices A3 and A4 according to the third embodiment and the fourth embodiment. In other words, in each of the semiconductor devices A1 and A2, the first conductive plate 31 and the output terminal 44 maybe formed integrally, and the third conductive plate 33 and the second input terminal 43 maybe formed integrally. The semiconductor devices A3 and A4 according to the third embodiment and the fourth embodiment have been described with an example where the first conductive plate 31 and the output terminal 44 are formed integrally, and the third conductive plate 33 and the second input terminal 43 are formed integrally. However, unlike this example, these elements may be bonded with a conductive bonding member in the same manner as in the semiconductor devices A1 and A2 according to the first embodiment and the second embodiment. In other words, in each of the semiconductor devices A3 and A4, the first conductive plate 31 and the output terminal 44 maybe made of different materials, and the first conductive plate 31 maybe bonded to the output terminal 44 with the conductive bonding member 731. Furthermore, the third conductive plate 33 and the second input terminal 43 maybe made of different materials, and the third conductive plate 33 maybe bonded to the second input terminal 43 with the conductive bonding member 733.

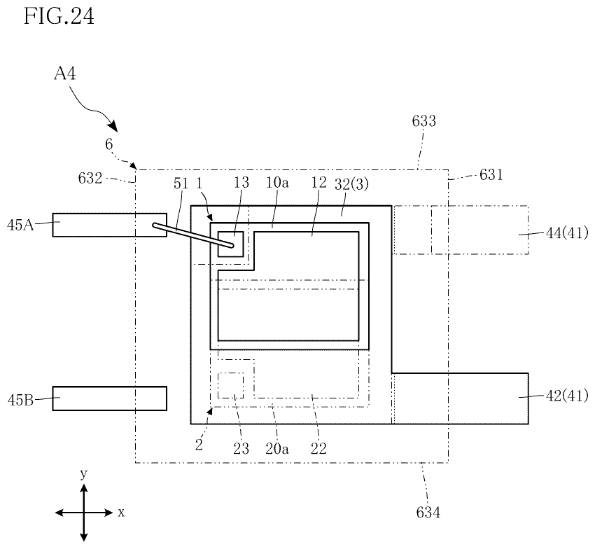

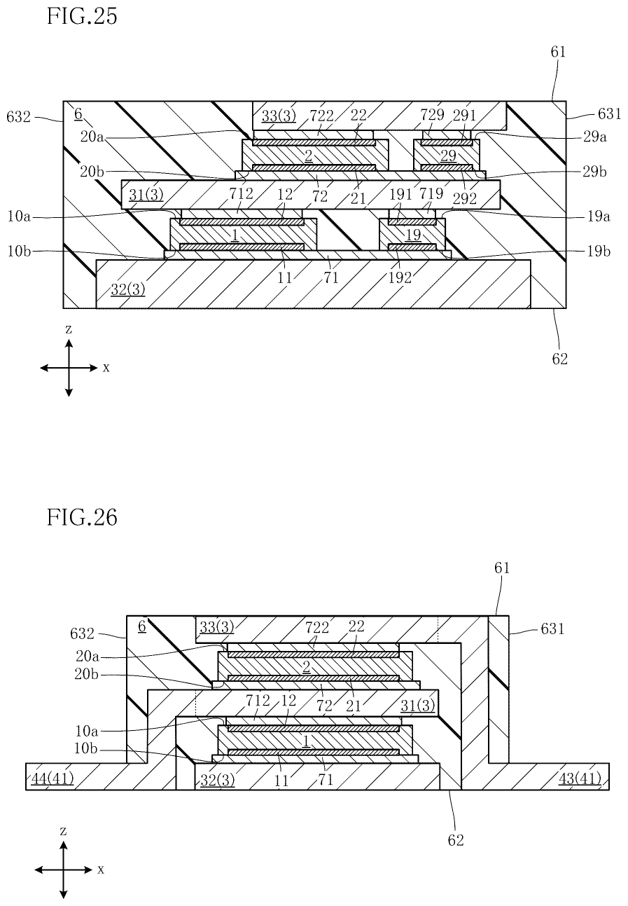

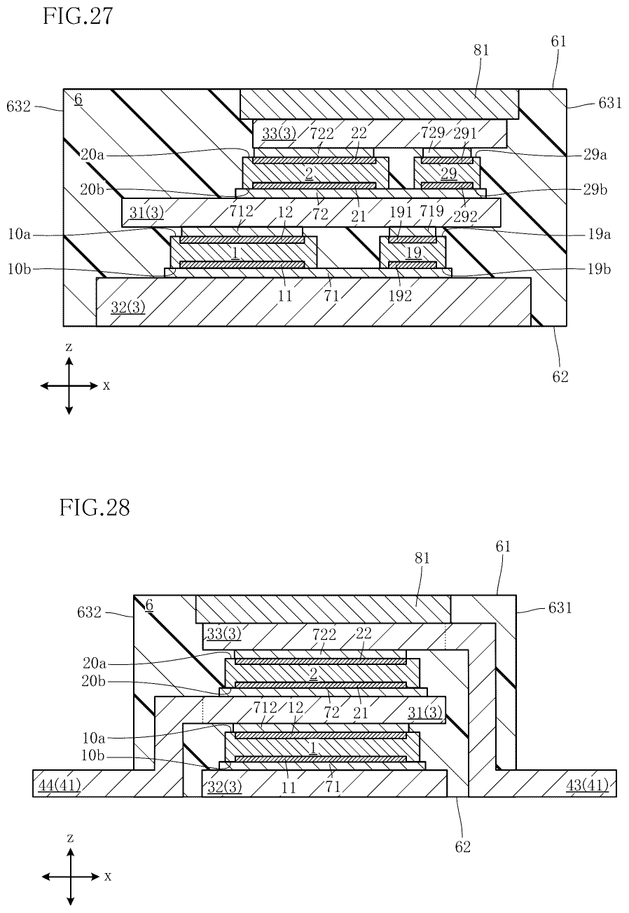

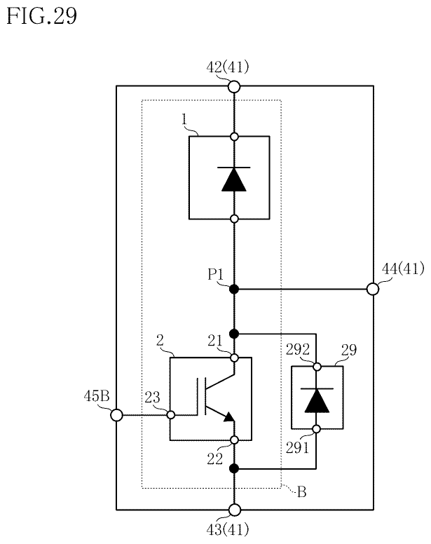

The first embodiment to the fourth embodiment have been described with an example where the upper surface (the surface facing upward in the thickness direction z) of the third conductive plate 33 is covered with the sealing resin 6. However, unlike this example, the upper surface of the third conductive plate 33 maybe exposed from the sealing resin 6. For example, FIG. 25 shows an example where, in the semiconductor device A1, the upper surface of the third conductive plate 33 is exposed from the sealing resin 6, and FIG. 26 shows an example where, in the semiconductor device A3, the upper surface of the third conductive plate 33 is exposed from the sealing resin 6. In such a configuration, the heat from each of the first semiconductor chip 1 and the second semiconductor chip 2 (in particular, the heat from the second semiconductor chip 2) is released to the outside via the third conductive plate 33, thereby improving the heat dissipation of the semiconductor device according to the variation. Note that instead of exposing the upper surface of the third conductive plate 33 from the sealing resin 6 as shown in the example of FIGS. 25 and 26, a plate member may be additionally attached to the upper surface of the third conductive plate 33 in the thickness direction z and the plate member may be exposed from the sealing resin 6. For example, FIG. 27 shows an example where, in the semiconductor device A1, a plate member 81 is provided on the upper surface of the third conductive plate 33, and FIG. 28 shows an example where, in the semiconductor device A3, the plate member 81 is provided on the upper surface of the third conductive plate 33. The constituent material of the plate member 81 maybe a metal material, a resin material, or a ceramic material (e.g., alumina). Note that the plate member 81 maybe in contact with an external cooling mechanism (not illustrated) for heat dissipation. When the plate member 81 is made of a metal material, for example, it is necessary to provide insulation between the external cooling mechanism and the plate member 81. Accordingly, it is preferable that an insulating sheet be provided between the external cooling mechanism and the plate member 81. Furthermore, the plate member 81 may have a sandwich structure made up of a conductive layer, an insulating layer, and a conductive layer formed in this order. In this case, it is not necessary to provide an insulating material between the external cooling mechanism and the plate member 81. Even with each of the configurations shown in FIGS. 27 and 28, the heat from each of the first semiconductor chip 1 and the second semiconductor chip 2 (in particular, the heat from the second semiconductor chip 2) is released to the outside via the third conductive plate 33 and the plate member 81, thereby improving the heat dissipation of the semiconductor device according to the variation. In order to improve heat dissipation as described above, it is preferable that the plate member 81 be made of a material having high thermal conductivity.

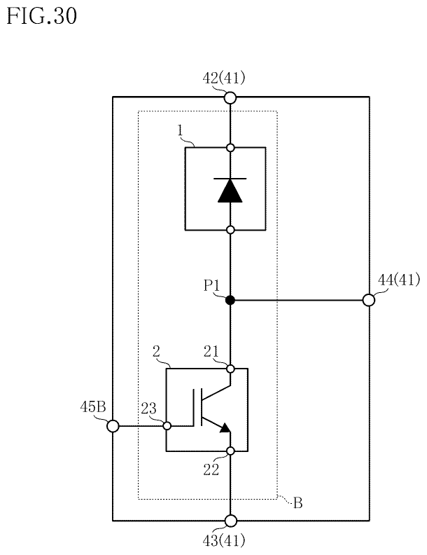

The first embodiment to the fourth embodiment have been described with an example where the first semiconductor chip 1 and the second semiconductor chip 2 are IGBTs (reverse-conducting IGBTs). However, unlike this configuration, one of the first semiconductor chip 1 and the second semiconductor chip 2 maybe a diode. For example, the first semiconductor chip 1 maybe a diode instead of an IGBT, so that the semiconductor device according to the present disclosure is configured as a chopper circuit as shown in FIG. 29. The chopper circuit shown in FIG. 29 maybe used as an AC-DC chopper circuit in which the first voltage is AC voltage and the second voltage is DC voltage. For example, the semiconductor device according to the present disclosure may be configured as a chopper circuit shown in FIG. 30. The chopper circuit shown in FIG. 30 maybe used as a DC-DC chopper circuit in which the first voltage is DC voltage and the second voltage is DC voltage. In the case of a DC-DC chopper circuit, the second semiconductor chip 2 may not be provided with a diode (the second diode chip 29 or the diode region 202) connected in reverse parallel to an IGBT. Although FIGS. 29 and 30 show examples where the first semiconductor chip 1 is configured with a diode, the first semiconductor chip 1 may be configured with an IGBT (reverse-conducting IGBT) and the second semiconductor chip 2 maybe configured with a diode.

The semiconductor device according to the present disclosure is not limited to the above embodiments. Various design changes can be made to the specific configurations of the elements of the semiconductor device of the present disclosure. For example, the semiconductor device according to the present disclosure covers the embodiments according to the following clauses.

Clause 1.

A semiconductor device comprising:
a first semiconductor chip including a first obverse surface and a first reverse surface spaced apart from each other in a thickness direction;
a second semiconductor chip including a second obverse surface and a second reverse surface spaced apart from each other in the thickness direction, and electrically connected in series to the first semiconductor chip; and
a conductive member including a first conductive plate electrically connected to the first semiconductor chip and the second semiconductor chip,
wherein at least one of the first semiconductor chip and the second semiconductor chip is an IGBT including a collector electrode, an emitter electrode, and a gate electrode, and
the first conductive plate is provided between the first semiconductor chip and the second semiconductor chip in the thickness direction.

Clause 2.

The semiconductor device according to clause 1,
wherein the conductive member includes a second conductive plate and a third conductive plate each spaced apart from the first conductive plate,
the second conductive plate and the third conductive plate are spaced apart from each other,
the first semiconductor chip is provided between the first conductive plate and the second conductive plate in the thickness direction, and
the second semiconductor chip is provided between the first conductive plate and the third conductive plate in the thickness direction.

Clause 3.

The semiconductor device according to clause 2,
wherein the first semiconductor chip and the second semiconductor chip overlap with each other as viewed in the thickness direction.

Clause 4.

The semiconductor device according to clause 2 or 3,
wherein the first semiconductor chip is a reverse-conducting IGBT including an IGBT region and a diode region, and includes a first collector electrode, a first emitter electrode, and a first gate electrode.

Clause 5.

The semiconductor device according to clause 2 or 3, further comprising a first diode chip connected to the first semiconductor chip,
wherein the first semiconductor chip includes a first collector electrode, a first emitter electrode, and a first gate electrode, and
the first diode chip includes an anode electrode connected to the first emitter electrode, and a cathode electrode connected to the first collector electrode.

Clause 6.

The semiconductor device according to clause 5,
wherein the second semiconductor chip overlaps with the first semiconductor chip and the first diode chip as viewed in the thickness direction, and
an area in which the second semiconductor chip overlaps with the first diode chip is larger than an area in which the second semiconductor chip overlaps with the first semiconductor chip as viewed in the thickness direction.

Clause 7.

The semiconductor device according to any of clauses 4 to 6,
wherein the first emitter electrode and the first gate electrode are provided on the first obverse surface of the first semiconductor chip, and the first collector electrode is provided on the first reverse surface,
the first collector electrode is bonded to the second conductive plate, and
the first emitter electrode is bonded to the first conductive plate.

Clause 8.

The semiconductor device according to clause 7,
wherein the first conductive plate does not overlap with the first gate electrode as viewed in the thickness direction.

Clause 9.
The semiconductor device according to any of clauses 2 to 8,
wherein the second semiconductor chip includes a second emitter electrode, a second collector electrode, and a second gate electrode.

Clause 10.

The semiconductor device according to clause 9,
wherein the second emitter electrode and the second gate electrode are provided on the second obverse surface of the second semiconductor chip, and the second collector electrode is provided on the second reverse surface,
the second collector electrode is bonded to the first conductive plate, and
the second emitter electrode is bonded to the third conductive plate.

Clause 11.

The semiconductor device according to clause 10,
wherein the third conductive plate does not overlap with the second gate electrode as viewed in the thickness direction.

Clause 12.

The semiconductor device according to any of clauses 2 to 11,
wherein a dimension of the second conductive plate in the thickness direction is larger than a dimension of each of the first conductive plate and the third conductive plate.

Clause 13.

The semiconductor device according to any of clauses 1 to 12, further comprising:
a plurality of power terminals each electrically connected to at least one of the first semiconductor chip and the second semiconductor chip; and
a signal terminal for inputting a gate signal to an IGBT that is one of the first semiconductor chip and the second semiconductor chip.

Clause 14.

The semiconductor device according to clause 13,
wherein the first semiconductor chip and the second semiconductor chip form a bridge in which the first semiconductor chip serving as an upper arm is connected to the second semiconductor chip serving as a lower arm, and
the plurality of power terminals include a first input terminal electrically connected to an end of the bridge, a second input terminal electrically connected to another end of the bridge, and an output terminal electrically connected to a connecting point between the first semiconductor chip and the second semiconductor chip.

Clause 15.

The semiconductor device according to clause 14,
wherein the first input terminal and the second input terminal are adjacent to each other in a first direction perpendicular to the thickness direction.

Clause 16.

The semiconductor device according to clause 14 or 15,
wherein the signal terminal is arranged on a side opposite from the first input terminal and the second input terminal with the first semiconductor chip and the second semiconductor chip therebetween.

Clause 17.

The semiconductor device according to any of clauses 13 to 16, further comprising a sealing resin covering a portion of the conductive member, a portion of each of the plurality of power terminals, a portion of the signal terminal, the first semiconductor chip, and the second semiconductor chip,
the sealing resin includes a resin obverse surface and a resin reverse surface spaced apart from each other in the thickness direction, and a plurality of resin side surfaces each connected to the resin obverse surface and the resin reverse surface, and
the plurality of resin side surfaces include a first resin side surface from which the signal terminal is exposed.

Clause 18.

The semiconductor device according to clause 17,
wherein the plurality of power terminals are exposed from the first resin side surface.

Clause 19.

The semiconductor device according to clause 17,
wherein at least one of the plurality of power terminals is exposed from a resin side surface which is one of the plurality of resin side surfaces different from the first resin side surface.

REFERENCE NUMERALS

| A1-A4: Semiconductor device | 1: First semiconductor chip |
|---|---|
| 10a: First obverse surface | 10b: First reverse surface |
| 101: IGBT region | 102: Diode region |
| 11: First collector electrode | 12: First emitter electrode |
| 13: First gate electrode | 19: First diode chip |
| 19a: Obverse surface | 19b: Reverse surface |
| 191: Anode electrode | 192: Cathode electrode |
| 2: Second semiconductor chip | 20a: Second obverse surface |
| 20b: Second reverse surface | 201: IGBT region |
| 202: Diode region | 21: Second collector electrode |
| 22: Second emitter electrode | 23: Second gate electrode |
| 29: Second diode chip | 29a: Obverse surface |
| 29b: Reverse surface | 291: Anode electrode |
| 292: Cathode electrode | 3: Conductive member |
| 31: First conductive plate | 32: Second conductive plate |
| 33: Third conductive plate | 41: Power terminal |
| 42: First input terminal | 43: Second input terminal |
| 44: Output terminal | 45A: First signal terminal |
| 45B: Second signal terminal | 51: First connecting member |
| 52: Second connecting member | 6: Sealing resin |
| 61: Resin obverse surface | 62: Resin reverse surface |
| 631-634: Resin side surface | |
| 71, 712, 719: Conductive bonding member | |
| 72, 722, 729: Conductive bonding member | |
| 731, 733: Conductive bonding member | |
| 81: Plate member | B: Bridge B |

1. A semiconductor device comprising:
a first semiconductor chip including a first obverse surface and a first reverse surface spaced apart from each other in a thickness direction;
a second semiconductor chip including a second obverse surface and a second reverse surface spaced apart from each other in the thickness direction, and electrically connected in series to the first semiconductor chip; and
a conductive member including a first conductive plate electrically connected to the first semiconductor chip and the second semiconductor chip,
wherein at least one of the first semiconductor chip and the second semiconductor chip is an IGBT including a collector electrode, an emitter electrode, and a gate electrode, and
the first conductive plate is provided between the first semiconductor chip and the second semiconductor chip in the thickness direction.

2. The semiconductor device according to claim 1,
wherein the conductive member includes a second conductive plate and a third conductive plate each spaced apart from the first conductive plate,
the second conductive plate and the third conductive plate are spaced apart from each other,
the first semiconductor chip is provided between the first conductive plate and the second conductive plate in the thickness direction, and
the second semiconductor chip is provided between the first conductive plate and the third conductive plate in the thickness direction.

3. The semiconductor device according to claim 2,
wherein the first semiconductor chip and the second semiconductor chip overlap with each other as viewed in the thickness direction.

4. The semiconductor device according to claim 2,
wherein the first semiconductor chip is a reverse-conducting IGBT including an IGBT region and a diode region, and includes a first collector electrode, a first emitter electrode, and a first gate electrode.

5. The semiconductor device according to claim 2, further comprising a first diode chip connected to the first semiconductor chip,
wherein the first semiconductor chip includes a first collector electrode, a first emitter electrode, and a first gate electrode, and
the first diode chip includes an anode electrode connected to the first emitter electrode, and a cathode electrode connected to the first collector electrode.

6. The semiconductor device according to claim 5,
wherein the second semiconductor chip overlaps with the first semiconductor chip and the first diode chip as viewed in the thickness direction, and
an area in which the second semiconductor chip overlaps with the first diode chip is larger than an area in which the second semiconductor chip overlaps with the first semiconductor chip as viewed in the thickness direction.

7. The semiconductor device according to claim 4,
wherein the first emitter electrode and the first gate electrode are provided on the first obverse surface of the first semiconductor chip, and the first collector electrode is provided on the first reverse surface,
the first collector electrode is bonded to the second conductive plate, and
the first emitter electrode is bonded to the first conductive plate.

8. The semiconductor device according to claim 7,
wherein the first conductive plate does not overlap with the first gate electrode as viewed in the thickness direction.

9. The semiconductor device according to claim 2,
wherein the second semiconductor chip includes a second emitter electrode, a second collector electrode, and a second gate electrode.

10. The semiconductor device according to claim 9,
wherein the second emitter electrode and the second gate electrode are provided on the second obverse surface of the second semiconductor chip, and the second collector electrode is provided on the second reverse surface,
the second collector electrode is bonded to the first conductive plate, and
the second emitter electrode is bonded to the third conductive plate.

11. The semiconductor device according to claim 10,
wherein the third conductive plate does not overlap with the second gate electrode as viewed in the thickness direction.

12. The semiconductor device according to claim 2,
wherein a dimension of the second conductive plate in the thickness direction is larger than a dimension of each of the first conductive plate and the third conductive plate.

13. The semiconductor device according to claim 1, further comprising:
a plurality of power terminals each electrically connected to at least one of the first semiconductor chip and the second semiconductor chip; and
a signal terminal for inputting a gate signal to an IGBT that is one of the first semiconductor chip and the second semiconductor chip.

14. The semiconductor device according to claim 13,
wherein the first semiconductor chip and the second semiconductor chip form a bridge in which the first semiconductor chip serving as an upper arm is connected to the second semiconductor chip serving as a lower arm, and
the plurality of power terminals include a first input terminal electrically connected to an end of the bridge, a second input terminal electrically connected to another end of the bridge, and an output terminal electrically connected to a connecting point between the first semiconductor chip and the second semiconductor chip.

15. The semiconductor device according to claim 14,
wherein the first input terminal and the second input terminal are adjacent to each other in a first direction perpendicular to the thickness direction.

16. The semiconductor device according to claim 14,
wherein the signal terminal is arranged on a side opposite from the first input terminal and the second input terminal with the first semiconductor chip and the second semiconductor chip therebetween.

17. The semiconductor device according to claim 13, further comprising a sealing resin covering a portion of the conductive member, a portion of each of the plurality of power terminals, a portion of the signal terminal, the first semiconductor chip, and the second semiconductor chip,
the sealing resin includes a resin obverse surface and a resin reverse surface spaced apart from each other in the thickness direction, and a plurality of resin side surfaces each connected to the resin obverse surface and the resin reverse surface, and
the plurality of resin side surfaces include a first resin side surface from which the signal terminal is exposed.

18. The semiconductor device according to claim 17,
wherein the plurality of power terminals are exposed from the first resin side surface.

19. The semiconductor device according to claim 17,
wherein at least one of the plurality of power terminals is exposed from a resin side surface which is one of the plurality of resin side surfaces different from the first resin side surface.
